(19) United States
(12) Patent Application Publication
(10) Pub. No.: US 2025/0248193 A1
(43) Pub. Date: Jul. 31, 2025

(54) DISPALY PANEL AND DISPLAY MODULE

(71) Applicant: Wuhan China Star Optoelectronics Technology Co., Ltd., Wuhan, Hubei (CN)

(72) Inventors: Peng HE, Wuhan, Hubei (CN); Yong XU, Wuhan, Hubei (CN); Bingkun YIN, Wuhan, Hubei (CN); Peitao ZHU, Wuhan, Hubei (CN); Li HU, Wuhan, Hubei (CN); Si XIE, Wuhan, Hubei (CN)

(73) Assignee: Wuhan China Star Optoelectronics Technology Co., Ltd., Wuhan, Hubei (CN)

(21) Appl. No.: 18/690,822

(22) PCT Filed: Feb. 4, 2024
(86) PCT No.: PCT/CN2024/075715

§ 371 Date: Mar. 11, 2024

(30) Foreign Application Priority Data
Jan. 31, 2024 (CN) 202410138753.2

(51) Int. Cl. H10H 29/32; H10F 55/15; H10H 29/49; H10H 29/855; H10H 29/856

(52) U.S. Cl. CPC H10H 29/32; H10F 55/15; H10H 29/49; H10H 29/8552; H10H 29/856

(57) ABSTRACT

The present disclosure provides a display panel and a display module, where the display panel includes a display area and a virtual terminal area; a plurality of sub-pixels of the display panel are located within the display area, and each of the sub-pixels includes at least first transistor; a light-sensing sensor is located within the virtual terminal area, and a portion of the film layer of the light-sensing sensor is disposed at the same layer as a portion of the film layer of the first transistor, so as to solve the technical problem that the existing externally-mounted light-sensing sensor is unfavorable to improvement of the screen-to-body ratios of the displays.

### TECHNICAL FIELD

The present disclosure relates to the field of display technologies, and in particular to a display panel and a display module.

### BACKGROUND

With the development of display technologies, Light-Emitting Diode (LED) displays have become a research hotspot currently in the display industry due to their properties of good reliability, small size of light-emitting cells, high brightness and the like. In order to reduce the power consumption of the displays, a light-sensing sensor may be externally mounted to an upper frame of the displays, and the brightness of the displays may be adjusted in real time by the light-sensing sensor sensing the intensity of the ambient light. For example, when the ambient light is dark, the brightness of the displays is automatically adjusted to be low brightness, thereby achieving the purpose of reducing the power consumption. However, a solution in which the light-sensing sensor is externally mounted may need a larger frame, which may be unfavorable to improvement of screen-to-body ratios of the displays.

### SUMMARY

The present disclosure provides a display panel and a display module, so as to alleviate a technical problem that the externally-mounted light-sensing sensor is unfavorable to improvement of the screen-to-body ratios of the displays.

To solve the above problems, the present disclosure may provide technical solutions as follows.

In a first aspect, embodiments of the present disclosure provide a display panel, including a display area and a binding area located at a side of the display area, where the binding area includes a terminal area and a virtual terminal area located at opposite sides of the terminal area, and the display panel further includes:
a substrate;
a plurality of sub-pixels arranged in array on the substrate and located within the display area, where each of the sub-pixels includes at least one first transistor; and
at least one light-sensing sensor located within the virtual terminal area, where a portion of a film layer of the light-sensing sensor is disposed at the same layer as a portion of a film layer of the first transistor.

In a second aspect, the embodiments of the present disclosure further provide a display module, including light emitting devices and a display panel, where the light emitting devices are disposed on the display panel, and the display panel includes a display area and a binding area located at a side of the display area, and where the binding area includes a terminal area and a virtual terminal area located at opposite sides of the terminal area, and the display panel further includes:
a substrate;
a plurality of sub-pixels arranged in array on the substrate and located within the display area, where each of the sub-pixels includes at least one first transistor; and
at least one light-sensing sensor located within the virtual terminal area, where a portion of a film layer of the light-sensing sensor is disposed at the same layer as a portion of a film layer of the first transistor,
where each of the light emitting devices corresponds to corresponding one of the sub-pixels on the display panel.

### BRIEF DESCRIPTION OF THE DRAWINGS

In order to more clearly illustrate the technical solutions in embodiments of the present disclosure, the accompanying drawings depicted in the description of the embodiments will be briefly described below. It will be apparent that the accompanying drawings in the following description are merely some embodiments of the present disclosure, and other drawings may be obtained from these drawings without creative effort by those skilled in the art.

FIG. 1 is a plane structure diagram of a display panel according to some embodiments of the present disclosure.

FIG. 2 is a sectional structure diagram of a display panel according to some embodiments of the present disclosure.

FIG. 3 is a schematic circuit diagram of a temperature sensor according to some embodiments of the present disclosure.

FIG. 4 is another sectional structure diagram of a display panel according to some embodiments of the present disclosure.

FIG. 5 is yet another sectional structure diagram of a display panel according to some embodiments of the present disclosure.

FIG. 6 is yet another sectional structure diagram of a display panel according to some embodiments of the present disclosure.

FIG. 7 is another schematic circuit diagram of a temperature sensor according to some embodiments of the present disclosure.

FIG. 8 is a plane structure diagram of a display module according to some embodiments of the present disclosure.

FIG. 9 is a sectional structure diagram of a portion of a display module according to some embodiments of the present disclosure.

### DETAILED DESCRIPTION

The description of the following embodiments refers to the attached drawings to illustrate specific embodiments in which the present disclosure can be implemented. The directional terms mentioned in the present disclosure, such as [up], [down], [front], [back], [left], [right], [inner], [outer], [side], etc., are only the direction of the attached drawings. Therefore, the directional terms used are used to describe and understand the present disclosure, rather than to limit the present disclosure. In the drawings, units with similar structures are indicated by the same reference numerals. In the drawings, thickness of layers and regions may be enlarged for clear understanding and ease of description. That is, the size and thickness of each of components shown in the drawings are arbitrarily shown, but the present disclosure is not limited thereto.

For the technical problem that the existing externally-mounted light-sensing sensor is unfavorable to improvement of the screen-to-body ratios of the displays, the present disclosure provides a display panel and a display module, so as to alleviate the technical problem that the existing externally-mounted light-sensing sensor is unfavorable to improvement of the screen-to-body ratios of the displays.

In some embodiments, embodiments of the present disclosure provide a display panel, including a display area and a binding area located at a side of the display area, where the binding area includes a terminal area and a virtual terminal area located at opposite sides of the terminal area, and the display panel further includes:
a substrate;
a plurality of sub-pixels arranged in array on the substrate and located within the display area, where each of the sub-pixels includes at least one first transistor; and
at least one light-sensing sensor located within the virtual terminal area, where a portion of a film layer of the light-sensing sensor is disposed at the same layer as a portion of a film layer of the first transistor.

In some embodiments, the first transistor includes a first active layer disposed on the substrate, and the display panel further includes both a first stack disposed at a side of the first active layer away from the substrate and a first source-drain layer; the light-sensing sensor includes a first semiconductor layer, a second semiconductor layer, and a first protective layer arranged in a stacked manner, where the first semiconductor layer is disposed at the same layer as the first active layer, and the first stack is provided with a first via hole at a position corresponding to the first semiconductor layer; and the second semiconductor layer is filled in the first via hole and in contact with the first semiconductor layer, and the first protective layer covers a side of the second semiconductor layer away from the first semiconductor layer.

In some embodiments, the light-sensing sensor further includes a third semiconductor layer disposed at a side of the first protective layer away from the second semiconductor layer, where the first protective layer is provided with a second via hole at a position corresponding to the second semiconductor layer, and the third semiconductor layer is connected to the second semiconductor layer through the second via hole.

In some embodiments, the display panel further includes a second stack disposed at a side of the first source-drain layer away from the first stack, and a first electrode disposed at a side of the second stack away from the first source-drain layer; and the second stack is provided with a third via hole at a position corresponding to the first protective layer, and a portion of the third semiconductor layer is located within the third via hole.

In some embodiments, the display panel further includes both a light shielding layer disposed at a side of the first electrode away from the second stack and a second protective layer located at a side of the light shielding layer away from the second stack, where the light shielding layer and the second protective layer are provided with a first opening at a position corresponding to the first electrode, and the light shielding layer is provided with a second opening at a position corresponding to the third via hole; and the second protective layer is further located within the second opening and the third via hole and provided with a third opening at a position corresponding to the second via hole, and the third semiconductor layer covers the second protective layer within the second opening and the third via hole.

In some embodiments, the display panel further includes a reflective layer located within the third via hole and provided with a fourth opening at a position corresponding to the second via hole, and the third semiconductor layer covers the reflective layer within the third via hole.

In some embodiments, the second stack includes a first planarization layer, a first passivation layer, a second planarization layer, and a second passivation layer, the first planar layer arranged in a stacked manner, where the first planarization layer is disposed on the first stack and the first source-drain layer, and the first electrode is disposed on the second passivation layer; the display panel further includes a second source-drain layer disposed between the first passivation layer and the second planarization layer, where the second source-drain layer is formed with a first auxiliary electrode connected between the first transistor and the first electrode; the first stack includes a first gate insulating layer, a second gate insulating layer and a first interlayer insulating layer arranged in a stacked manner, where the first gate insulating layer is disposed on the first active layer and the first semiconductor layer, and the first source-drain layer is disposed on the first interlayer insulating layer; and the display panel further includes a first gate layer located between the first gate insulating layer and the second gate insulating layer, and a second gate layer located between the second gate insulating layer and the first interlayer insulating layer.

In some embodiments, the second stack includes a first planarization layer and a second planarization layer arranged in a stacked manner, where the first planarization layer is disposed on the first stack and the first source-drain layer, and the first electrode is disposed on the second planarization layer; the display panel further includes a second source-drain layer disposed between the first planarization layer and the second planarization layer, where the second source-drain layer is formed with a first auxiliary electrode connected between the first transistor and the first electrode; the first stack includes a first gate insulating layer, a second gate insulating layer and a first interlayer insulating layer arranged in a stacked manner, where the first gate insulating layer is disposed on the first active layer and the first semiconductor layer, and the first source-drain layer is disposed on the first interlayer insulating layer; and the display panel further includes a first gate layer located between the first gate insulating layer and the second gate insulating layer, and a second gate layer located between the second gate insulating layer and the first interlayer insulating layer.

In some embodiments, the display panel further includes a plurality of temperature sensors located within the display area, where a portion of a film layer of each of the temperature sensors is disposed at the same layer as a portion of a film layer of the first transistor, and an arrangement density of the temperature sensors close to the binding area is greater than an arrangement density of the temperature sensors away from the binding area; and
where each of gaps is provided between two adjacent ones of the sub-pixels and the temperature sensors are disposed within at least a portion of the gaps.

In some embodiments, each of the sub-pixels further includes at least one second transistor connected to the first transistor, where the first transistor is a polysilicon transistor and the second transistor is an oxide transistor; and a material of the second semiconductor layer includes a metal oxide semiconductor material.

In some embodiments, each of the temperature sensors includes a third transistor and a fourth transistor connected to the third transistor, where the third transistor is disposed at the same layer as the first transistor and the fourth transistor is disposed at the same layer as the second transistor.

In some embodiments, the embodiments of the present disclosure further provide a display module, including light emitting devices and the display panel of any one of the above embodiments, where the light emitting devices are disposed on the display panel, and each of the light emitting devices corresponds to corresponding one of the sub-pixels on the display panel.

In the display panel and the display module provided in the embodiments of the present disclosure, the display panel includes the display area and the binding area located at a side of the display area, where the binding area includes the terminal area and the virtual terminal area located at opposite sides of the terminal area; the display panel further includes the substrate, the plurality of sub-pixels disposed on the substrate and at least one light-sensing sensor, where the plurality of sub-pixels are located within the display area, and each of the sub-pixels includes at least one first transistor; the light-sensing sensor is located within the virtual terminal area, and a portion of the film layer of the light-sensing sensor is disposed at the same layer as a portion of the film layer of the first transistor. According to the present disclosure, by integrating the light-sensing sensor into the virtual terminal area of the display panel, it is possible to provide the light-sensing sensor having a small volume without additionally occupying a space on the display panel, thereby solving the technical problem that the existing externally-mounted light-sensing sensor is unfavorable to improvement of the screen-to-body ratios of the displays.

The display panel and the display module of the present disclosure will be described below in detail with reference to the accompanying drawings and detailed description.

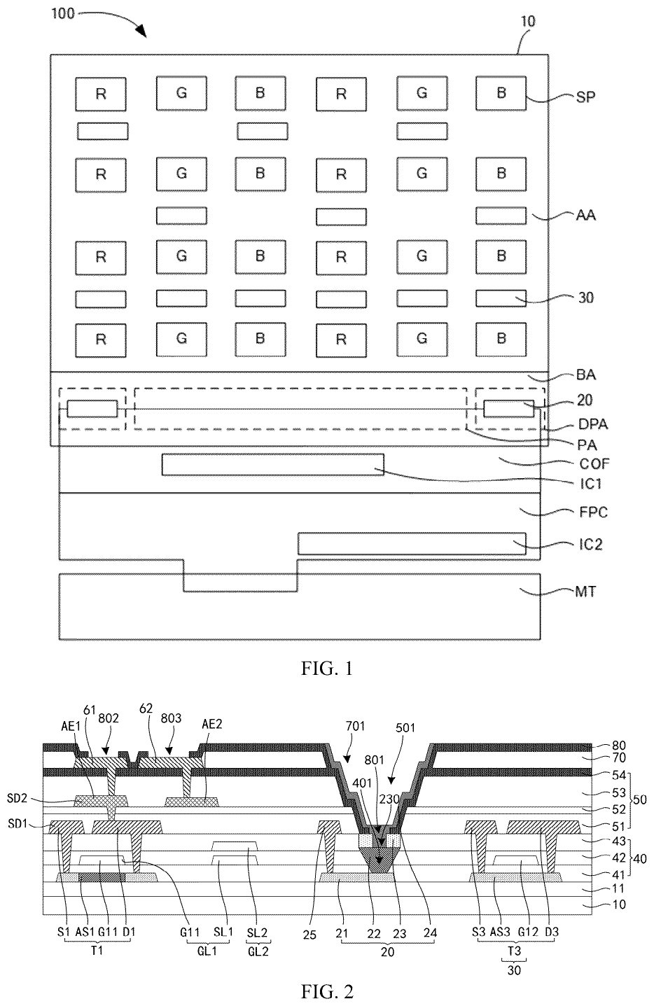

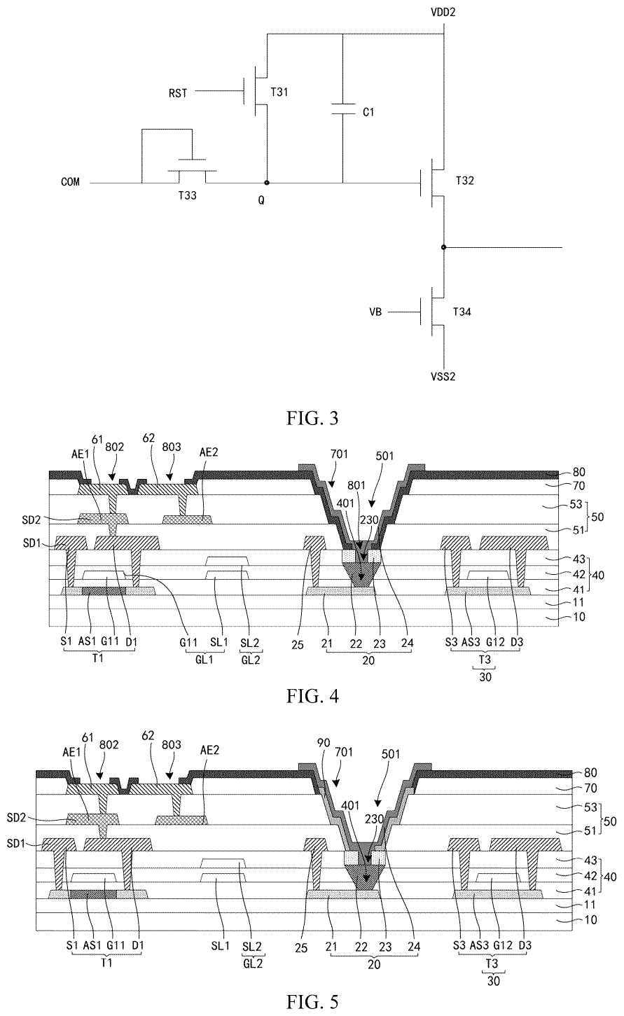

Referring to FIGS. 1 and 2, FIG. 1 is a plane structure diagram of a display panel according to some embodiments of the present disclosure, FIG. 2 is a sectional structure diagram of a display panel according to some embodiments of the present disclosure, and FIG. 3 is a schematic circuit diagram of a temperature sensor according to some embodiments of the present disclosure. Referring to FIG. 1, the display panel 100 includes a display area AA and a binding area BA located at a side of the display area AA, where the binding area BA includes a terminal area PA and a virtual terminal area DPA located at opposite sides of the terminal area PA. The terminal area PA and the virtual terminal area DPA are each provided with one or more binding terminals. A difference between the terminal area PA and the virtual terminal area DPA is that the terminals of the terminal area PA are configured to connect an internal line and an external line of the display panel 100, and the terminals of the virtual terminal area DPA are not configured to connect the internal line and the external line of the display panel 100. For example, a chip-on-film (COF) and/or a flexible circuit board (FPC) are bound to the display panel 100 by the terminals of the terminal area PA and the binding terminals of the virtual binding area BA, and are connected to the internal line of the display panel 100 by the terminals of the terminal area PA, and the terminals of the virtual terminal area DPA are in a floating state, for improving the appearance consistency of the binding area BA and improving the binding stability of the COF and the FPC with the display panel 100. The COF is provided with a first driving chip IC1, and the FPC is provided with a second driving chip IC2.

The display panel 100 further includes a substrate 10 and a plurality of sub-pixels SP, a plurality of temperature sensors 30, and at least one light-sensing sensor 20 disposed on the substrate 10. The plurality of sub-pixel SP are arranged in array on the substrate 10 and located within the display area AA with each of gaps being between two adjacent ones of the sub-pixels SP. The plurality of sub-pixels SP includes red sub-pixels R, green sub-pixels G, and blue sub-pixels B. The plurality of temperature sensors 30 are disposed within a portion of the gaps, and configured to detect the temperature of the display panel 100 in real time, convert change of the detected temperature into an electrical signal, and transmit the electrical signal to a controller MT by the FPC for calculation. The controller MT adjusts a heat dissipation device to change the temperature of the display panel 100 in real time according to a result of the calculation. Alternatively, an arrangement density of the temperature sensors 30 close to the binding area BA is greater than that of the temperature sensors 30 away from the binding area BA to improve the reliability of the temperature collected by the temperature sensors 30.

The at least one light-sensing sensor 20 is located within the virtual terminal area DPA. The light-sensing sensor 20 is configured to collect the intensity of the ambient light and convert the collected light signal into an electric signal, which is transmitted to the controller MT by the FPC for calculation. The controller MT adjusts a brightness of a screen for the display panel in real time according to a result of the calculation. By integrating the light-sensing sensor 20 into the virtual terminal area DPA of the display panel 100 without additionally occupying a space on the display panel 100, the technical problem that the existing externally-mounted light-sensing sensor 20 is unfavorable to improvement of the screen-to-body ratios of the displays is solved.

Referring to FIG. 2, each of the sub-pixels SP includes at least one first transistor T1 disposed on the substrate 10. Alternatively, a buffer layer 11 may be further disposed between the first transistor T1 and the substrate 10. The buffer layer 11 may be formed of an inorganic material such as silicon oxide (SiOx), silicon nitride (SiNx), silicon oxynitride (SiON), or the like to prevent undesirable impurities or contaminants (such as moisture, oxygen, and the like) from diffusing from the flexible substrate 10 into devices that may be damaged by these impurities or contaminants. At the same time, the buffer layer 11 may further provide a flat top surface to facilitate the preparation of other film layer structures on the buffer layer 11.

A portion of the film layer of the light-sensing sensor 20 is disposed at the same layer as a portion of the film layer of the first transistor T1, and a portion of the film layer of the temperature sensor 30 is disposed at the same layer as a portion of the film layer of the first transistor T1. That is, the light-sensing sensor 20 and the temperature sensor 30 are both formed in the same process as the first transistor T1 of the sub-pixel SP to enable the light-sensing sensor 20 and the temperature sensor 30 to be integrated onto the display panel 100, so that the light-sensing sensor 20 and the temperature sensor 30 both having a smaller volume can be provided, avoiding the use of an externally-mounted sensor to occupy a larger frame.

The first transistor T1 includes a first active layer AS1 disposed on the substrate 10. The display panel 100 further includes a first stack 40 disposed at a side of the first active layer AS1 away from the substrate 10 and a first source-drain layer SD1, where the first stack 40 is disposed between the first active layer AS1 and the first source-drain layer SD1, the first source-drain layer SD1 is a metal conductive layer, and the first source-drain layer SD1 is formed with a first source S1 and a first drain D1 of the first transistor T1. The light-sensing sensor 20 includes a first semiconductor layer 21, a second semiconductor layer 22, and a first protective layer 23 arranged in a stacked manner. The first semiconductor layer 21 is disposed at the same as the first active layer AS1, that is, the first semiconductor layer 21 and the first active layer AS1 are made of the same material, for example, a semiconductor material such as polysilicon.

It should be noted that “disposed at the same layer” in the present disclosure means that a film layer formed of the same material is patterned in a preparation process to obtain at least two different structures and then dispose the at least two different structures at the same layer. For example, when the first semiconductor layer 21 and the first active layer AS1 of the present embodiment are obtained by patterning the same semiconductor material layer, the first semiconductor layer 21 and the first active layer AS1 are disposed at the same layer.

The first stack 40 is provided with a first via hole 401 at a position corresponding to the first semiconductor layer 21, the second semiconductor layer 22 is filled in the first via hole 401 and is in contact with the first semiconductor layer 21, and a material of the second semiconductor layer 22 includes amorphous silicon or the like. Of course, the first stack 40 is further provided with one or more via holes in a portion of an area corresponding to the first active layer AS1, and the first source S1 and the first drain D1 of the first transistor T1 are connected to the first active layer AS1 through corresponding ones of the via holes, respectively. Specifically, the first active layer AS1 includes a channel area and source and drain areas located at opposite sides of the channel area, where the first source S1 is connected to the source area through corresponding one of the via holes, and the first drain D1 is connected to the drain area through corresponding one of the via holes. The source area and the drain area are formed by ion doping of a semiconductor material, and the first semiconductor layer 21 is also formed by ion doping of a semiconductor layer material.

The first protective layer 23 covers a side of the second semiconductor layer 22 away from the first semiconductor layer 21. The first protective layer 23 is configured to protect the second semiconductor layer 22 from damage when the first source-drain layer SD1 is etched. The material of the first protective layer 23 is an etching-resistant inorganic material such as silicon oxide or the like. Alternatively, the first protective layer 23 is also filled in the first via hole 401. In this case, an upper surface of the first protective layer 23 is flush with that of the first stack 40. The upper surface refers to a surface of each of structures at a side of the structure away from the substrate 10.

The first stack 40 includes a first gate insulating layer 41, a second gate insulating layer 42, and a first interlayer insulating layer 43 arranged in a stacked manner, where the first gate insulating layer 41 is disposed on the first active layer AS1 and the first semiconductor layer 21, the first source-drain layer SD1 is disposed on the first interlayer insulating layer 43, and all of the first gate insulating layer 41, the second gate insulating layer 42, and the first interlayer insulating layer 43 are inorganic insulating layers, such as silicon nitride layers.

The display panel 100 further includes a first gate layer GL1 located between the first gate insulating layer 41 and the second gate insulating layer 42 and a second gate layer GL2 located between the second gate insulating layer 42 and the first interlayer insulating layer 43. Both the first gate layer GL1 and the second gate layer GL2 are metal conductive layers, the first gate layer GL1 is formed with a first gate G11 of the first transistor T1 and a first signal wiring SL1, and the second gate layer GL2 is formed with a second signal wiring SL2.

Each of the temperature sensors 30 includes a third transistor T3, which is disposed at the same layer as the first transistor T1. Specifically, the third transistor T3 includes a third active layer AS3, a third gate G12, a third source S3, and a third drain D3, where the third active layer AS3 is disposed at the same layer as the first active layer AS1, the third gate G12 is disposed at the same layer as the first gate G11, and the third source S3 and the third drain D3 are disposed at the same layer as the first source S1. That is, when the first source S1 and the first drain D1 of the first transistor T1 are formed in the first source-drain layer SD1, the third source S3 and the third drain D3 of the third transistor T3 are further formed in the first source-drain layer SD1. Alternatively, the first source-drain layer SD1 is further formed with a connection electrode 25 of the light-sensing sensor 20. It should be noted that FIG. 2 schematically shows only a portion of film structures of the sub-pixels SP, the light-sensing sensor 20, and the temperature sensors 30, which is not limited herein. For example, each of the sub-pixels SP of the present disclosure may further include a storage capacitor and more transistors, the light-sensing sensor 20 may further include at least one transistor connected to the first semiconductor layer 21 by the connection electrode 25, and the temperature sensor 30 may further include a capacitor and more transistors. For example, the temperature sensor 30 includes four transistors (such as T31, T32, T33, T34) and one capacitor (such as C1), as shown in FIG. 3.

Continuing to refer to FIG. 2, the light-sensing sensor 20 further includes a third semiconductor layer 24 disposed at a side of the first protective layer 23 away from the second semiconductor layer 22, the first protective layer 23 is provided with a second via hole 230 at a position corresponding to the second semiconductor layer 22, and the third semiconductor layer 24 is connected to the second semiconductor layer 22 through the second via hole 230. Alternatively, an opening area of the second via hole 230 constitutes 80%-100% of the upper surface area of the second semiconductor layer 22 to increase a contact area between the third semiconductor layer 24 and the second semiconductor layer 22. The opening area of the second via hole 230 refers to an area of an opening of the second via hole 230 close to the second semiconductor layer 22, that is, an area of a hole bottom of the second via hole 230. More specifically, the opening area of the second via hole 230 refers to an area of an orthographic projection of the second via hole 230 on the second semiconductor layer 22. The upper surface area of the second semiconductor layer 22 refers to the area of the upper surface of the second semiconductor layer 22, and the upper surface of the second semiconductor layer 22 refers to the surface of the second semiconductor layer 22 at a side of the second semiconductor layer 22 away from the substrate, that is, the surface on which the second semiconductor layer 22 contacts the first protective layer 23.

The display panel 100 further includes a second stack 50 disposed at a side of the first source-drain layer SD1 away from the first stack 40, and a first electrode 61 disposed at a side of the second stack 50 away from the first source-drain layer SD1. The second stack 50 is provided with a third via hole 501 at a position corresponding to the first protective layer 23, and a portion of the third semiconductor layer 24 is located within the third via hole 501. The first semiconductor layer 21 is an N-type semiconductor layer, the second semiconductor layer 22 is an intrinsic semiconductor layer, and the third semiconductor layer 24 is a P-type semiconductor layer and has high light transmittance.

The display panel 100 further includes a light shielding layer 70 disposed at a side of the first electrode 61 away from the second stack 50, and a second protective layer 80 disposed at a side of the light shielding layer 70 away from the second stack 50. The light shielding layer 70 is configured to perform light shielding for the transistor and the signal wiring on the display panel 100, and a material of the light shielding layer 70 includes a light shielding material such as a Black Matrix (BM). The second protective layer 80 is configured to protect and flatten the display panel 100, and the material of the second protective layer 80 includes an inorganic material such as silicon nitride.

The light shielding layer 70 and the second protective layer 80 are provided with a first opening 802 at a position corresponding to the first electrode 61, the light shielding layer 70 is provided with a second opening 701 at a position corresponding to the third via hole 501, the second protective layer is further located within the second opening 701 and the third via hole 501 and provided with a third opening 801 at a position corresponding to the second via hole 230. That is, the second protective layer 80 covers a side wall of the second opening 701 formed in the light shielding layer 70, a side wall of the third via hole 501 formed in the second stack 50, and an upper surface of the first protective layer 23. The third semiconductor layer 24 covers the second protective layer 80 within the second opening 701 and the third via hole 501.

Alternatively, the display panel 100 further includes a second electrode 62 disposed at the same layer as the first electrode 61, where the first electrode 61 and the second electrode 62 are separated by the second protective layer 80 to be insulated from each other. The second protective layer 80 and the light shielding layer 70 are further provided with a fifth opening 803 at a position corresponding to the second electrode 62, where the first opening 802 and the fifth opening 803 of the light shielding layer 70 are communicated with each other.

The second stack 50 includes a first planarization layer 51, a first passivation layer 52, a second planarization layer 53, and a second passivation layer 54 arranged in a stacked manner, where the first planarization layer 51 is disposed on both the first stack 40 and the first source-drain layer SD1, and the first electrode 61 is disposed on the second passivation layer 54. The display panel 100 further includes a second source-drain layer SD2 disposed between the first passivation layer 52 and the second planarization layer 53, where the second source-drain layer SD2 is a metal conductive layer and formed with a first auxiliary electrode AE1 and a second auxiliary electrode AE2, and the first auxiliary electrode AE1 is connected between the first transistor T1 and the first electrode 61 to enable the first electrode 61 to be electrically connected to the first transistor T1. Specifically, the first electrode 61 is electrically connected to the first drain D1 of the first transistor T1. The second auxiliary electrode AE2 is connected to the second electrode 62.

The first planarization layer 51 and the second planarization layer 53 are organic planarization layers, the first passivation layer 52 and the second passivation layer 54 are inorganic insulating layers, and the first passivation layer 52 and the second passivation layer 54 are configured to protect the first planarization layer 51 and the second planarization layer 53, respectively, to avoid damage to the first planarization layer 51 and the second planarization layer 53 when dry etching is performed on the first planarization layer 51 and the second planarization layer 53. It should be noted that, when materials of the second source-drain layer SD2, the first source-drain layer SD1, and the first electrode 61 in the present embodiment are the same, such as titanium-aluminum-titanium stack, the second source-drain layer SD2 and the first electrode 61 may be etched by a dry etching process so as to avoid the occurrence of side-etching, but there is a risk that the organic planarization layers may be damaged by the dry etching. Therefore, an inorganic insulating layer is disposed on the organic planarization layers in the present embodiment for protection to avoid damage to the first planarization layer 51 and the second planarization layer 53 when the dry etching is performed on the first planarization layer 51 and the second planarization layer 53.

In some embodiments, please refer to FIGS. 1-4, FIG. 4 is another sectional structure diagram of a display panel 100 according to some embodiments of the present disclosure. Referring to FIG. 4, unlike the above-described embodiments, the first semiconductor layer 21 is a P-type semiconductor layer, and the third semiconductor layer 24 is an N-type semiconductor layer. The first semiconductor layer 21 is disposed at the same layer as the first active layer AS1, and the first semiconductor layer 21 and the first active layer AS1 may use the same doping process to save the number of photomasks and reduce the cost. The third semiconductor layer 24 is a transparent electrode layer, and a material of the third semiconductor layer 24 includes an N-type semiconductor material such as N+A-Si, ITO, In₂O₃, and ZnO. When the material of the third semiconductor layer 24 is an N-type semiconductor material such as ZnO, the ZnO can be directly grown within the third via hole 501, so that ion doping of the third semiconductor layer 24 is not required to further reduce the number of photomasks.

Further, the second stack 50 includes a first planarization layer 51 and a second planarization layer 53 arranged in a stacked manner, where the first planarization layer 51 is disposed on the first stack 40 and the first source-drain layer SD1, and the first electrode 61 is disposed on the second planarization layer 53. The display panel 100 further includes a second source-drain layer SD2 disposed between the first planarization layer 51 and the second planarization layer 53, where the second source-drain layer SD2 is formed with a first auxiliary electrode AE1 connected between the first transistor T1 and the first electrode 61. The second source-drain layer SD2, the first source-drain layer SD1, and the first electrode 61 have different materials from each other. For example, the first source-drain layer SD1 is a titanium-aluminum-titanium stack, the second source-drain layer SD2 is an electroplated copper layer, and the first electrode 61 is a molybdenum-aluminum-molybdenum stack. Since the first source-drain layer SD1 is an electroplated copper layer, there is no occurrence of side-etching. Therefore, the first source-drain layer SD1 can be etched by a wet etching process in the present embodiment. When the wet etching process is used, no damage is caused to the organic planarization layer. Therefore, there is no need to dispose an inorganic insulating layer on the organic planarization layer, so that the number of photomasks can be further reduced and the cost can be reduced. Other illustration refers to the above-mentioned embodiments, which is repeatedly described herein.

In some embodiments, referring to FIGS. 1-5, FIG. 5 is yet another sectional structure diagram of a display panel 100 according to some embodiments of the present disclosure. Referring to FIG. 5, unlike the above-described embodiments, the display panel further includes a reflective layer 90 located within the third via hole 501 and provided with a fourth opening at a position corresponding to the second via hole 230, and the third semiconductor layer 24 covers the reflective layer 90 within the third via hole 501. Alternatively, the material of the reflective layer 90 includes a metallic material having reflective properties. By disposing the reflective layer 90 within the third via hole 501 in the present embodiment, the reflective layer 90 can reflect light onto the light-sensing sensor 20, thereby improving the light absorption efficiency of the light-sensing sensor 20, and further improving the sensitivity of the light-sensing sensor 20. Other illustration refers to the above-mentioned embodiments, which is repeatedly described herein.

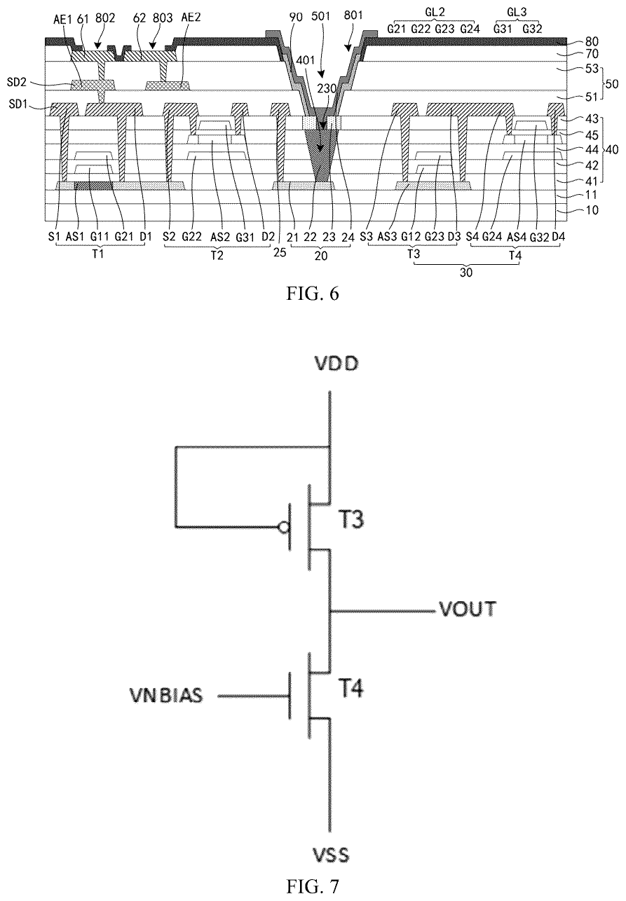

In some embodiments, referring to FIGS. 1-7, FIG. 6 is yet another sectional structure diagram of a display panel 100 according to some embodiments of the present disclosure, and FIG. 7 is another schematic circuit diagram of a temperature sensor 30 according to some embodiments of the present disclosure. Referring to FIG. 6, unlike the above-described embodiments, each of the sub-pixels SP further includes at least one second transistor T2 connected to the first transistor T1, where the first transistor T1 is a polysilicon transistor and the second transistor T2 is an oxide transistor. Correspondingly, each of the temperature sensors 30 includes a third transistor T3 and a fourth transistor T4 connected to the third transistor T3, where the third transistor T3 is disposed at the same layer as the first transistor T1 and the fourth transistor T4 is disposed at the same layer as the second transistor T2.

Specifically, the first transistor T1 includes a first active layer AS1, a first gate G11, a second gate G21, a first source S1, and a first drain D1. Correspondingly, the third transistor T3 includes a third active layer AS3, a third gate G12, a fourth gate G23, a third source S3, and a third drain D3. The second transistor T2 includes a fifth gate G22, a second active layer AS2, a sixth gate G31, a second source S2, and a second drain D2. Correspondingly, the fourth transistor T4 includes a seventh gate G24, a fourth active layer AS4, an eighth gate G32, a fourth source S4, and a fourth drain D4. The first gate G11 and the third gate G12 are formed by the first gate layer GL1. The second gate G21, the fourth gate G23, the fifth gate G22, and the seventh gate G24 are formed by the second gate layer GL2. The sixth gate G31 and the eighth gate G32 are formed by the third gate layer GL3. The materials of the first active layer AS1 and the third active layer AS3 are both polysilicon, such as Low Temperature Poly Silicon (LTPS). The materials of the second active layer AS2 and the fourth active layer AS4 are both metal oxide semiconductor materials, such as Indium Gallium Zinc Oxide (IGZO). By fabricating the transistor using the LTPS and the IGZO, an Low Temperature Polycrystalline Oxide (LTPO) architecture can be formed to realize switching of high-low frequencies, so that the temperature sensor 30 can be provided with a small number of transistors, thereby reducing an occupied area of the temperature sensor 30. Illustratively, as shown in FIG. 7, the temperature sensor 30 of the present embodiment includes two transistors (T3 and FIG. 4). Compared to the temperature sensor 30 including the four transistors and the one capacitor shown in FIG. 3, the temperature sensor 30 of the present embodiment can reduce the occupied area of the temperature sensor 30 due to the smaller number of transistors included in the temperature sensor 30.

Alternatively, the material of the second semiconductor layer 22 includes a metal oxide semiconductor material, such as Indium Gallium Zinc Oxide (IGZO). By forming the second semiconductor layer 22 with the IGZO, since the IGZO itself has a higher absorption coefficient for light than amorphous silicon, a concentration of light-generated carriers excited by the IGZO is increased correspondingly, and the sensitivity characteristic of light is increased.

In addition, unlike the above-described embodiments, the first stack 40 includes a first gate insulating layer 41, a second gate insulating layer 42, a second interlayer insulating layer 44, a third gate insulating layer 45, and a first interlayer insulating layer 43 arranged in a stacked manner. Other illustration refers to the above-mentioned embodiments, which is repeatedly described herein.

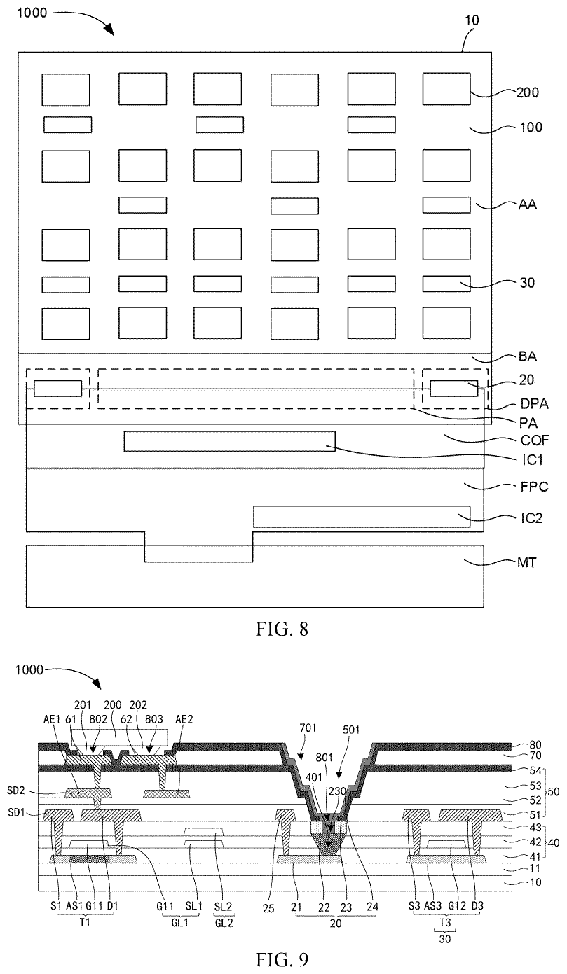

Based on the same inventive concept, the embodiments of the present disclosure further provide a display module. Referring to FIGS. 1 to 9, FIG. 8 is a plane structure diagram of a display module according to some embodiments of the present disclosure, and FIG. 9 is a sectional structure diagram of a portion of a display module according to some embodiments of the present disclosure. Referring to FIG. 8, the display module 1000 includes light emitting devices 200 and the display panel of any one of the above embodiments, where the light emitting devices 200 are disposed on the display panel, and each of the light emitting devices 200 corresponds to corresponding one of the sub-pixels SP on the display panel 100, so that the light emitting devices 200 are arranged in array on the display panel 100. The display module further includes both a chip-on-film (COF) and/or a flexible circuit board (FPC) bound to the display panel 100 and a controller MT, where a first driving chip IC1 is disposed on the COF, and a second driving chip IC2 is disposed on the FPC.

Specifically, referring to FIG. 9, the light emitting device 200 are bound onto the display panel 100. Each of the light emitting devices 200 includes a cathode 201 and an anode 202 insulated from each other, where the cathode 201 is electrically connected to the first electrode 61 of the display panel 100, and the anode 202 is electrically connected to the second electrode 62 of the display panel 100, so as to realize electrical connection of the light emitting device 200 to the display panel 100. The display panel 100 is configured to provide a driving signal to each of the light emitting device 200 to enable the light emitting device 200 to emit light. Alternatively, each of the light emitting devices 200 includes an Micro Light-Emitting Diode (Micro-LED) chip, an Mini Light-Emitting Diode (Mini-LED) chip, an Light-Emitting Diode (LED) chip, or the like.

Accordingly, the display module 1000 includes an LED display module, an Micro LED display module, an Mini LED display module, or the like.

Illustratively, the display module 1000 is applied to a display device that may be an electronic device having a display function, such as a television, a mobile phone, a tablet computer, a computer display, a game device, a digital camera, an on-board navigator, an electronic billboard, an automatic teller machine, a wearable device, or the like, where the wearable device may be a display device such as a smart wristband, smart glasses, a smart watch, a smart decoration, or the like.

It can be known according to the above embodiments that:
the present disclosure provides a display panel and a display module, where the display panel includes the display area and the binding area located at a side of the display area, where the binding area includes the terminal area and the virtual terminal area located at opposite sides of the terminal area; the display panel further includes the substrate, the plurality of sub-pixels disposed on the substrate and at least one light-sensing sensor, where the plurality of sub-pixels are located within the display area, and each of the sub-pixels includes at least one first transistor; the light-sensing sensor is located within the virtual terminal area, and a portion of the film layer of the light-sensing sensor is disposed at the same layer as a portion of the film layer of the first transistor. According to the present disclosure, by integrating the light-sensing sensor into the virtual terminal area of the display panel, it is possible to provide the light-sensing sensor having a small volume without additionally occupying a space on the display panel, thereby solving the technical problem that the existing externally-mounted light-sensing sensor is unfavorable to improvement of the screen-to-body ratios of the displays.

In the foregoing embodiments, descriptions of the embodiments are emphasized. A portion that is not described in detail in some embodiments may refer to related descriptions in another embodiment.

The embodiments of the present disclosure are described in detail above. In this specification, principles and implementations of the present disclosure are illustrated by applying specific examples herein. The description of the above embodiments is only used to help understand the technical solutions and core ideas of the present disclosure; those of ordinary skill in the art should understand that it is still possible to modify the technical solutions recorded in the foregoing embodiments, and these modifications or replacements do not cause the essence of the corresponding technical solutions to deviate from the scope of the technical solutions of the embodiments of the present disclosure.

What is claimed is:

1. A display panel, comprising: a display area and a binding area located at a side of the display area, wherein the binding area comprises a terminal area and a virtual terminal area located at opposite sides of the terminal area, and the display panel further comprises:
a substrate;
a plurality of sub-pixels arranged in array on the substrate and located within the display area, wherein each of the sub-pixels comprises at least one first transistor; and
at least one light-sensing sensor located within the virtual terminal area, wherein a portion of a film layer of the light-sensing sensor is disposed at the same layer as a portion of a film layer of the first transistor.

2. The display panel of claim 1, wherein
the first transistor comprises a first active layer disposed on the substrate, and the display panel further comprises both a first stack disposed at a side of the first active layer away from the substrate and a first source-drain layer;
the light-sensing sensor comprises a first semiconductor layer, a second semiconductor layer, and a first protective layer arranged in a stacked manner, wherein the first semiconductor layer is disposed at the same layer as the first active layer, and the first stack is provided with a first via hole at a position corresponding to the first semiconductor layer; and
wherein the second semiconductor layer is filled in the first via hole and in contact with the first semiconductor layer, and the first protective layer covers a side of the second semiconductor layer away from the first semiconductor layer.

3. The display panel of claim 2, wherein
the light-sensing sensor further comprises: a third semiconductor layer disposed at a side of the first protective layer away from the second semiconductor layer, wherein the first protective layer is provided with a second via hole at a position corresponding to the second semiconductor layer, and the third semiconductor layer is connected to the second semiconductor layer through the second via hole.

4. The display panel of claim 3, further comprising: both a second stack disposed at a side of the first source-drain layer away from the first stack and a first electrode disposed at a side of the second stack away from the first source-drain layer; and the second stack is provided with a third via hole at a position corresponding to the first protective layer, and a portion of the third semiconductor layer is located within the third via hole.

5. The display panel of claim 4, further comprising: both a light shielding layer disposed at a side of the first electrode away from the second stack and a second protective layer located at a side of the light shielding layer away from the second stack, wherein the light shielding layer and the second protective layer are provided with a first opening at a position corresponding to the first electrode, and the light shielding layer is provided with a second opening at a position corresponding to the third via hole; and
wherein the second protective layer is further located within the second opening and the third via hole and provided with a third opening at a position corresponding to the second via hole, and the third semiconductor layer covers the second protective layer within the second opening and the third via hole.

6. The display panel of claim 4, further comprising: a reflective layer located within the third via hole and provided with a fourth opening at a position corresponding to the second via hole, and the third semiconductor layer covers the reflective layer within the third via hole.

7. The display panel of claim 4, wherein
the second stack comprises a first planarization layer, a first passivation layer, a second planarization layer, and a second passivation layer arranged in a stacked manner, wherein the first planarization layer is disposed on the first stack and the first source-drain layer, and the first electrode is disposed on the second passivation layer;
the display panel further comprises a second source-drain layer disposed between the first passivation layer and the second planarization layer, wherein the second source-drain layer is formed with a first auxiliary electrode connected between the first transistor and the first electrode;
the first stack comprises a first gate insulating layer, a second gate insulating layer and a first interlayer insulating layer arranged in a stacked manner, wherein the first gate insulating layer is disposed on the first active layer and the first semiconductor layer, and the first source-drain layer is disposed on the first interlayer insulating layer; and the display panel further comprises a first gate layer located between the first gate insulating layer and the second gate insulating layer, and a second gate layer located between the second gate insulating layer and the first interlayer insulating layer.

8. The display panel of claim 4, wherein
the second stack comprises a first planarization layer and a second planarization layer arranged in a stacked manner, wherein the first planarization layer is disposed on the first stack and the first source-drain layer, and the first electrode is disposed on the second planarization layer;
the display panel further comprises a second source-drain layer disposed between the first planarization layer and the second planarization layer, wherein the second source-drain layer is formed with a first auxiliary electrode connected between the first transistor and the first electrode;
the first stack comprises a first gate insulating layer, a second gate insulating layer and a first interlayer insulating layer arranged in a stacked manner, wherein the first gate insulating layer is disposed on the first active layer and the first semiconductor layer, and the first source-drain layer is disposed on the first interlayer insulating layer; and
the display panel further comprises a first gate layer located between the first gate insulating layer and the second gate insulating layer, and a second gate layer located between the second gate insulating layer and the first interlayer insulating layer.

9. The display panel of claim 2, further comprising a plurality of temperature sensors located within the display area, wherein a portion of a film layer of each of the temperature sensors is disposed at the same layer as a portion of a film layer of the first transistor, and an arrangement density of the temperature sensors close to the binding area is greater than an arrangement density of the temperature sensors away from the binding area; and
wherein each of gaps is provided between two adjacent ones of the sub-pixels and the temperature sensors are disposed within at least a portion of the gaps.

10. The display panel of claim 9, wherein each of the sub-pixels further comprises at least one second transistor connected to the first transistor, wherein the first transistor is a polysilicon transistor and the second transistor is an oxide transistor; and a material of the second semiconductor layer comprises a metal oxide semiconductor material.

11. The display panel of claim 10, wherein
each of the temperature sensors comprises a third transistor and a fourth transistor connected to the third transistor, wherein the third transistor is disposed at the same layer as the first transistor and the fourth transistor is disposed at the same layer as the second transistor.

12. A display module, comprising: light emitting devices and a display panel,
wherein the light emitting devices are disposed on the display panel, and the display panel comprises a display area and a binding area located at a side of the display area, wherein the binding area includes a terminal area and a virtual terminal area located at opposite sides of the terminal area and the display panel further comprises:
a substrate;
a plurality of sub-pixels arranged in array on the substrate and located within the display area, wherein each of the sub-pixels comprises at least one first transistor; and
at least one light-sensing sensor located within the virtual terminal area, wherein a portion of a film layer of the light-sensing sensor is disposed at the same layer as a portion of a film layer of the first transistor,
wherein each of the light emitting devices corresponds to corresponding one of the sub-pixels on the display panel.

13. The display module of claim 12, wherein
the first transistor comprises a first active layer disposed on the substrate, and the display panel further comprises both a first stack disposed at a side of the first active layer away from the substrate and a first source-drain layer;
the light-sensing sensor comprises a first semiconductor layer, a second semiconductor layer, and a first protective layer arranged in a stacked manner, wherein the first semiconductor layer is disposed at the same layer as the first active layer, and the first stack is provided with a first via hole at a position corresponding to the first semiconductor layer; and
wherein the second semiconductor layer is filled in the first via hole and in contact with the first semiconductor layer, and the first protective layer covers a side of the second semiconductor layer away from the first semiconductor layer.

14. The display module of claim 13, wherein
the light-sensing sensor further comprises: a third semiconductor layer disposed at a side of the first protective layer away from the second semiconductor layer, wherein the first protective layer is provided with a second via hole at a position corresponding to the second semiconductor layer, and the third semiconductor layer is connected to the second semiconductor layer through the second via hole.

15. The display module of claim 14, wherein the display panel further comprises: both a second stack disposed at a side of the first source-drain layer away from the first stack and a first electrode disposed at a side of the second stack away from the first source-drain layer; and the second stack is provided with a third via hole at a position corresponding to the first protective layer, and a portion of the third semiconductor layer is located within the third via hole.

16. The display module of claim 15, wherein the display panel further comprises: both a light shielding layer disposed at a side of the first electrode away from the second stack and a second protective layer located at a side of the light shielding layer away from the second stack, wherein the light shielding layer and the second protective layer are provided with a first opening at a position corresponding to the first electrode, and the light shielding layer is provided with a second opening at a position corresponding to the third via hole; and
wherein the second protective layer is further located within the second opening and the third via hole and provided with a third opening at a position corresponding to the second via hole, and the third semiconductor layer covers the second protective layer within the second opening and the third via hole.

17. The display module of claim 15, wherein the display panel further comprises: a reflective layer located within the third via hole and provided with a fourth opening at a position corresponding to the second via hole, and the third semiconductor layer covers the reflective layer within the third via hole.

18. The display module of claim 15, wherein the second stack comprises a first planarization layer, a first passivation layer, a second planarization layer, and a second passivation layer arranged in a stacked manner, wherein the first planarization layer is disposed on both the first stack and the first source-drain layer, and the first electrode is disposed on the second passivation layer;
the display panel further comprises a second source-drain layer disposed between the first passivation layer and the second planarization layer, wherein the second source-drain layer is formed with a first auxiliary electrode connected between the first transistor and the first electrode;
the first stack comprises a first gate insulating layer, a second gate insulating layer and a first interlayer insulating layer arranged in a stacked manner, wherein the first gate insulating layer is disposed on the first active layer and the first semiconductor layer, and the first source-drain layer is disposed on the first interlayer insulating layer; and the display panel further comprises a first gate layer located between the first gate insulating layer and the second gate insulating layer, and a second gate layer located between the second gate insulating layer and the first interlayer insulating layer.

19. The display module of claim 15, wherein the second stack comprises a first planarization layer and a second planarization layer arranged in a stacked manner, wherein the first planarization layer is disposed on the first stack and the first source-drain layer, and the first electrode is disposed on the second planarization layer;
the display panel further comprises a second source-drain layer disposed between the first planarization layer and the second planarization layer, wherein the second source-drain layer is formed with a first auxiliary electrode connected between the first transistor and the first electrode;
the first stack comprises a first gate insulating layer, a second gate insulating layer and a first interlayer insulating layer arranged in a stacked manner, wherein the first gate insulating layer is disposed on the first active layer and the first semiconductor layer, and the first source-drain layer is disposed on the first interlayer insulating layer; and
the display panel further comprises a first gate layer located between the first gate insulating layer and the second gate insulating layer, and a second gate layer located between the second gate insulating layer and the first interlayer insulating layer.

20. The display module of claim 13, wherein the display panel further comprises a plurality of temperature sensors located within the display area, wherein a portion of a film layer of each of the temperature sensors is disposed at the same layer as a portion of a film layer of the first transistor, and an arrangement density of the temperature sensors close to the binding area is greater than an arrangement density of the temperature sensors away from the binding area; and
wherein each of gaps is provided between two adjacent ones of the sub-pixels and the temperature sensors are disposed within at least a portion of the gaps.
